(19) United States
(12) Patent Application Publication
(10) Pub. No.: US 2022/0206393 A1
(43) Pub. Date: Jun. 30, 2022

(54) TRANSFER PLATE, METHOD FOR MANUFACTURING TRANSFER PLATE, AND SUBSTRATE TREATING APPARATUS

(71) Applicant: SEMES CO., LTD., Chungcheongnam-do (KR)

(72) Inventors: Jaeoh BANG, Seoul (KR); Jong Gun LEE, Jeollanam-do (KR); Tae Hoon LEE, Gyeonggi-do (KR)

(21) Appl. No.: 17/547,309

(22) Filed: Dec. 10, 2021

(30) Foreign Application Priority Data
Dec. 24, 2020 (KR) 10-2020-0182768

(51) Int. Cl. G03F 7/16

(52) U.S. Cl. CPC G03F 7/168

(57) ABSTRACT

Disclosed is a method for manufacturing a cooling plate for cooling a substrate, including an operation of manufacturing a coolant pipe by using a tubular pipe, an operation of inserting the coolant pipe into a casting mold that defines a plate, and an operation of casting the cooling plate by injecting a molten metal into the casting mold.

### CROSS-REFERENCE TO RELATED APPLICATIONS

A claim for priority under 35 U.S.C. § 119 is made to Korean Patent Application No. 10-2020-0182768 filed on Dec. 24, 2020, in the Korean Intellectual Property Office, the entire contents of which are hereby incorporated by reference.

### BACKGROUND

Embodiments of the inventive concept described herein relate to a transfer plate, a method for manufacturing the same, and a substrate treating apparatus.

Various processes such as cleaning, deposition, photographing, etching, and ion implantation are performed to manufacture a semiconductor device. Among the processes, a deposition process and an application process are used as a process of forming a film on a substrate. In general, the deposition process is a process of forming a film on a substrate by depositing a process gas on the substrate, and the application process is a process of forming a liquid film by applying a treatment liquid onto the substrate.

A baking process for baking the substrate is performed before and after a film is formed on the substrate. The baking process is a process of heating the substrate to a process temperature or more in a closed space. In the baking process performed after the film is formed on the substrate, a photoresist film is heated and volatilized such that a thickness of the film is adjusted to a preset thickness.

FIG. 1A is a view illustrating a conventional cooling plate.

The cooling plate is transferred while a substrate “W” is spaced apart from a base plate 1 in a bake chamber. The cooling plate has a coolant passage in an interior thereof.

Generally, the cooling plate is manufactured through brazing or press-fitting. As shown in FIG. 1A, in the brazing, a passage is formed in an aluminum metal plate through grooving, and another plate of the same material is bonded thereto. However, the brazed cooling plate is oxidized and corroded in an interior of the passage, which causes the passage to be blocked by foreign substances such as aluminum oxide.

As in FIG. 1B, in the press-fitting, after an aluminum metal plate is grooved, it is press-fitted with a passage pipe of a dissimilar metal (for example, SUS). The press-fitting shows an excellent anti-oxidation property and an anti-corrosion property, but deteriorates a cooling performance and anodizing is impossible.

### SUMMARY

Embodiments of the inventive concept provide a transfer plate having a dissimilar material structure having a tubular passage, through which a fluid flow, a method for manufacturing a transfer unit, and a substrate treating apparatus.

Embodiments of the inventive concept also provide a method for manufacturing plate, a process of which is simple.

Embodiments of the inventive concept also provide a transfer plate that may use a coolant pipe of a stainless steel material, a method for manufacturing a transfer unit, and a substrate treating apparatus

Embodiments of the inventive concept also provide a transfer plate, in which interfaces between a member constituting a body of a transfer plate and a coolant pipe of a stainless steel material may be excellently bonded to each other, a method for manufacturing a transfer unit, and a substrate treating apparatus

The problems that are to be solved by the inventive concept are not limited to the above-mentioned problems, and the unmentioned problems will be clearly understood by those skilled in the art to which the inventive concept pertains from the specification and the accompanying drawings.

According to an embodiment, a method for manufacturing a cooling plate for cooling a substrate includes an operation of manufacturing a coolant pipe by using a tubular pipe, an operation of inserting the coolant pipe into a casting mold that defines the cooling plate, and an operation of casting the cooling plate by injecting a molten metal into the casting mold.

Furthermore, the manufacturing of the coolant pipe may include surface-treating an outer peripheral surface of the tubular pipe to form an intermetallic compound between interfaces, in the casting of the cooling plate.

Furthermore, the surface-treating of the outer peripheral surface of the tubular pipe is any one of Zn plating, Ni plating, and Ni—P plating.

Furthermore, the manufacturing of the coolant pipe may include bending the tubular pipe in correspondence to a shape of a cooling passage that is to be defined in the cooling plate.

Furthermore, materials of the tubular pipe and the molten metal may be different materials.

Furthermore, the tubular pipe may be formed of a stainless steel material, and the molten metal may be formed of an aluminum or an aluminum alloy material.

Furthermore, the casting of the cooling plate may be insert die casting (IDC).

Furthermore, the method may further include surface-treating the cooling plate through anodizing after the casting of the cooling plate.

According to another embodiment, there is provided a cooling plate for cooling a substrate, which is integrally cast by inserting a coolant pipe bent in a shape of a cooling passage, and wherein a material of the coolant pipe is different from a casting material.

Furthermore, the material of the coolant pipe may be a stainless steel material, and the casting material may be aluminum or an aluminum alloy.

Furthermore, the coolant pipe may have a plate film on an outer peripheral surface thereof.

Furthermore, the plating film may be formed of any one of Zn, Ni, and Ni—P.

Furthermore, the cooling plate for cooling the substrate may include a guide hole that extends from an outer surface thereof to an inner side.

According to another embodiment, a substrate treating apparatus may include a housing, a heating unit located in the housing and having a heating plate that heats a substrate, a transfer unit located in the housing and having a transfer plate that transfers the substrate, and a cooling unit that cools the heating plate or the heated substrate, the substrate treating apparatus includes the transfer plate, the cooling unit includes a cooling passage provided in an interior of the transfer plate, and the transfer plate is an integral cast, into which a coolant pipe that provides the cooling passage through casting.

Furthermore, an outer peripheral surface of the coolant pipe may be surface-treated.

Furthermore, the surface-treating of the outer peripheral surface of the coolant pipe may be any one of Zn plating, Ni plating, and Ni—P plating.

Furthermore, materials of the coolant pipe and the cast may be different materials.

Furthermore, the coolant pipe may be formed of a stainless steel material, and the material of the cast may be an aluminum or aluminum alloy material.

Furthermore, the heating unit may further include lift pins that moves in a pin hole formed in the heating plate upwards and downwards and feed the substrate to the transfer unit, the transfer unit further may include a driving member that moves the transfer plate between a first location that is adjacent to a first side wall having a substrate entrance of the housing and a second location corresponding to an upper side of the heating plate, and the transfer plate may include a guide hole, into which the lift pins are inserted such that an interference or a collision with the lift pins is prevented when the transfer plate move from the first location to the second location.

Furthermore, the guide hole may extend from an outer surface of the transfer plate to an inner side.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIGS. 1A and 1B are views illustrating a structure of a conventional transfer plate;

FIG. 2 is a view schematically illustrating a substrate treating apparatus according to an embodiment of the inventive concept;

FIG. 3 is a cross-sectional view of the substrate treating apparatus that shows an application block or a development block of FIG. 2;

FIG. 4 is a plan view illustrating the substrate treating apparatus of FIG. 2;

FIG. 5 is a view illustrating an example of a hand of a transfer robot of FIG. 4;

FIG. 6 is a plan view schematically illustrating an example of a heat treatment chamber of FIG. 4;

FIG. 7 is a front view of the heat treatment chamber of FIG. 6;

FIG. 8 is a view illustrating the substrate treating apparatus provided in a heating unit of FIG. 7.

FIG. 9 is a view illustrating a transfer plate according to the inventive concept;

FIG. 10 is a cross-sectional view taken along line A-A of FIG. 9;

FIG. 11 is a flowchart illustrating a method for manufacturing a transfer plate;

FIG. 12 is a view illustrating a process of manufacturing a coolant pipe;

FIG. 13 is a view illustrating a process of inserting a coolant pipe; and

FIGS. 14 and 15 are views illustrating a process of casting a transfer plate.

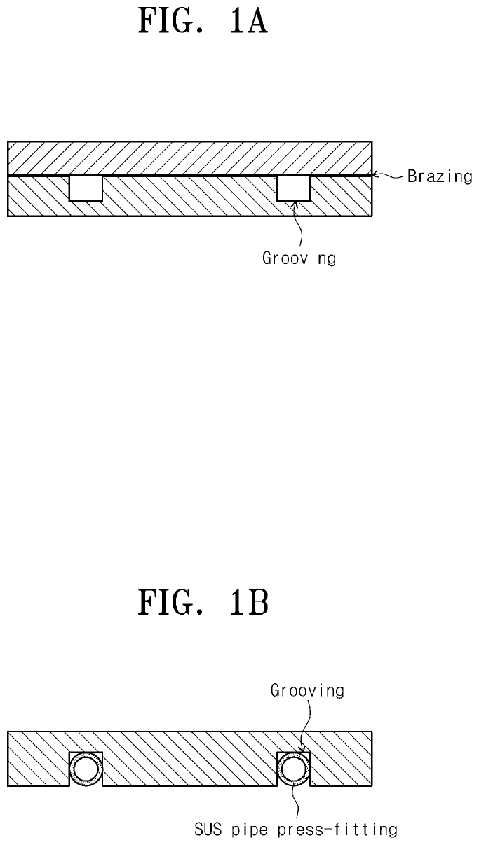

### DETAILED DESCRIPTION

The above and other advantages and features of the inventive concept, and methods of the inventive concept for achieving them will become apparent from the following description of the following embodiments which are given in conjunction with the accompanying drawings and will be described below in detail. However, the inventive concept is not limited to the embodiments, which will be disclosed hereinafter, and the inventive concept is defined only by the scope of the claims. Although not defined, all the terms (including technical or scientific terms) used herein may have the same meanings that are generally accepted by the common technologies in the field to which the present invention pertains. A general description of the known configurations may be omitted not to make the essence of the inventive concept obscure. In the drawings of the inventive concept, the same reference numerals are used to denote the same or similar configurations if possible. For easy understanding of the inventive concept, some configurations may be rather exaggerated or downscaled in the drawings.

The terminologies used herein are provided only to describe specific embodiments, and are not intended to limit the inventive concept. The terms of a singular form may include plural forms unless otherwise specified. The terms “including” and “having” are used to designate that the features, the numbers, the steps, the operations, the elements, the parts, or combination thereof described in the specification are present, and may be understood that one or more other features, numbers, step, operations, elements, parts, or combinations thereof may be added.

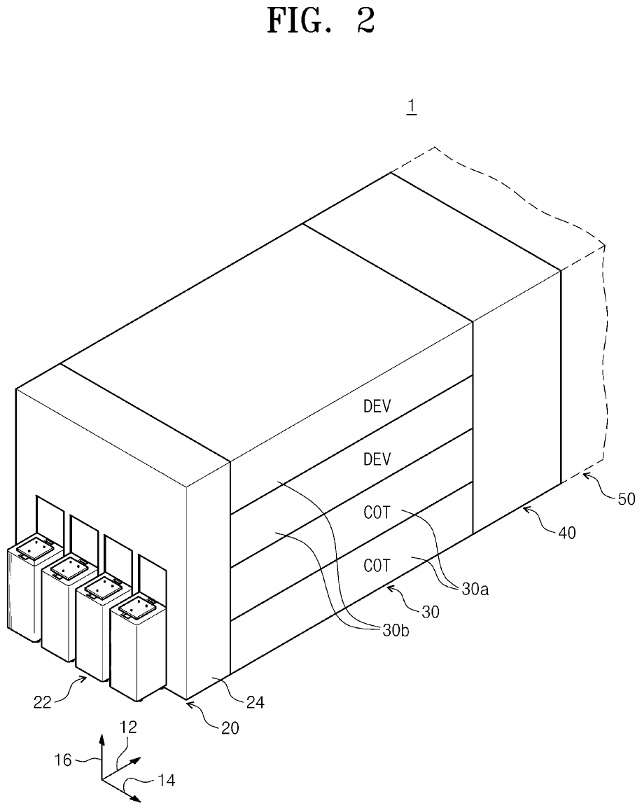

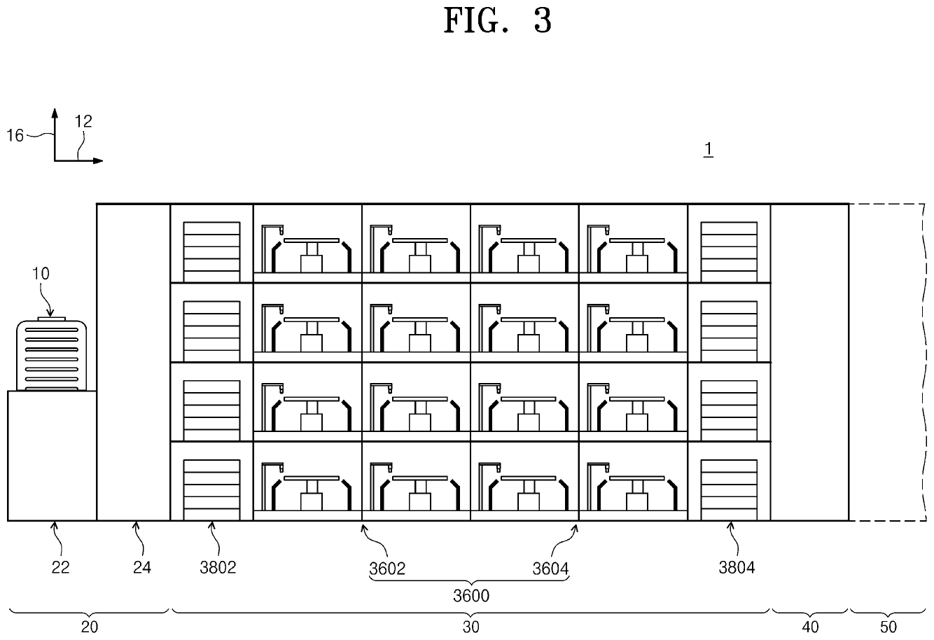

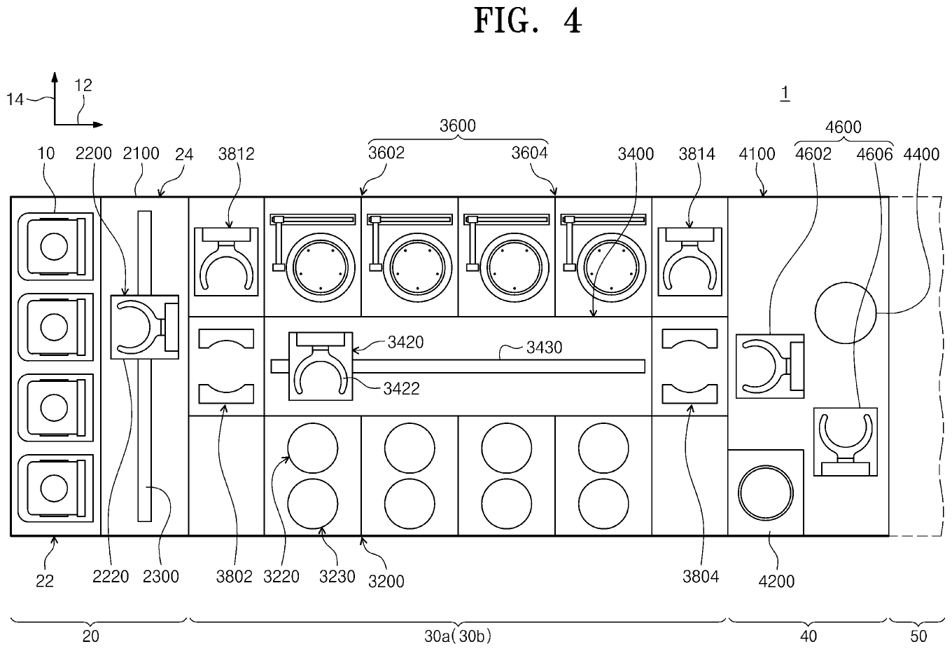

FIG. 2 is a view schematically illustrating a substrate treating apparatus according to an embodiment of the inventive concept. FIG. 3 is a cross-sectional view of the substrate treating apparatus that shows an application block or a development block of FIG. 2. FIG. 4 is a plan view illustrating the substrate treating apparatus of FIG. 2.

Referring to FIGS. 2 to 4, a substrate treating apparatus 1 includes an index module 20, a treatment module 30, and an interface module 40.

According to an embodiment, the index module 20, the treatment module 30, and the interface module 40 are sequentially disposed in a row. Hereinafter, a direction, in which the index module 20, the treatment module 30, and the interface module 40 are arranged, will be referred to as a first direction 12, a direction that is perpendicular to the first direction 12 when viewed from the top will be referred to as a second direction 14, and a direction that is perpendicular to both the first direction 12 and the second direction 14 will be referred to as a third direction 16.

The index module 20 transfers a substrate “W” from a container 10, in which the substrate “W” is received, to the treatment module 30, and the completely treated substrate “W” is received in the container 10. A lengthwise direction of the index module 20 is the second direction 14. The index module 20 includes a load port 22 and an index frame 24. The load port 22 is located on an opposite side to the treatment module 30 with respect to the index frame 24. The container 10, in which the substrates “W” are received, is positioned on the load port 22. A plurality of load ports 22 may be provided, and the plurality of load ports 22 may be disposed along the second direction 14.

The container 10 may be the closed container 10 such as a front open unified pod (FOUP). The container 10 may be positioned on the load port 22 by a transfer unit (not illustrated) such as an overhead transfer, an overhead conveyor, or an automatic guided vehicle, or an operator.

An index robot 2200 is provided in an interior of the index frame 24. A guide rail 2300, a lengthwise direction of which is the second direction 14, may be provided in the index frame 24, and the index robot 2200 may be movable on the guide rail 2300. The index robot 2200 includes a hand 2220, on which the substrate “W” is positioned, and the hand 2220 may be moved forwards and rearwards, be rotated about the third direction 16, and be moved along the third direction 16.

The treatment module 30 performs an application process and a development process on the substrate “W”. The treatment module 30 has an application block 30a and a development block 30b. The application block 30a performs the application process on the substrate “W”, and the development block 30b performs the development process on the substrate “W”. A plurality of application blocks 30a may be provided, and are stacked on each other. A plurality of development blocks 30b are provided, and the development blocks 30b are stacked on each other.

According to the embodiment of FIG. 2, two application blocks 30a are provided and two development blocks 30b are provided. The application blocks 30a may be disposed below the development blocks 30b. According to an embodiment, the two application blocks 30a may perform the same process, and may have the same structure. Furthermore, the two development blocks 30b may perform the same process, and may have the same structure.

Referring to FIG. 2 again, the application block 30a has a heat treatment chamber 3200, a transfer chamber 3400, a liquid treatment chamber 3600, and a buffer chamber 3800. The heat treatment chamber 3200 performs a heat treatment process on the substrate “W”. The heat treatment process may include a cooling process and a heating process. The liquid treatment chamber 3600 may supply a liquid onto the substrate “W” and forms a liquid film. The liquid film may be a photoresist film or anti-reflection film. The transfer chamber 3400 transfers the substrate “W” in the application block 30a between the heat treatment chamber 3200 and the liquid treatment chamber 3600.

The transfer chamber 3400 is configured such that the lengthwise direction thereof is in parallel to the first direction 12. A transfer robot 3422 is provided in the transfer chamber 3400. The transfer robot 3422 transfers the substrate between the heat treatment chamber 3200, the liquid treatment chamber 3600, and the buffer chamber 3800. According to an embodiment, the transfer robot 3422 has a hand 3420, on which the substrate “W” is positioned, and the hand 3420 may be moved forwards and rearwards, be rotated about the third direction 16, and be moved along the third direction 16. A guide rail 3430, a lengthwise direction of which is parallel to the first direction 12, may be provided in the transfer chamber 3400, and the transfer robot 3422 may be movable on the guide rail 3300.

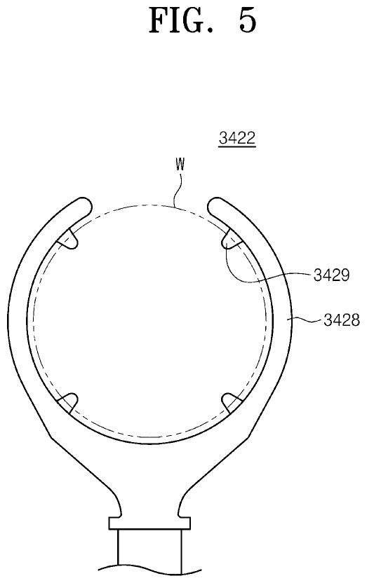

FIG. 5 is a view illustrating an example of a hand of a transfer robot of FIG. 2.

Referring to FIG. 5, the hand 3420 has a base 3428 and a support boss 3429. The base 3428 may have an annular ring shape, a circumferential portion of which is bent. The base 3428 has an inner diameter that is larger than a diameter of the substrate “W”. The support boss 3429 extends inwards from the base 3428. A plurality of support bosses 3429 are provided, and support an edge area of the substrate “W”. According to an example, four support bosses may be provided at an equal interval.

A plurality of heat treatment chambers 3200 are provided. The heat treatment chambers 3200 may be arranged along the first direction 12. The heat treatment chambers 3200 are located on one side of the transfer chamber 3400.

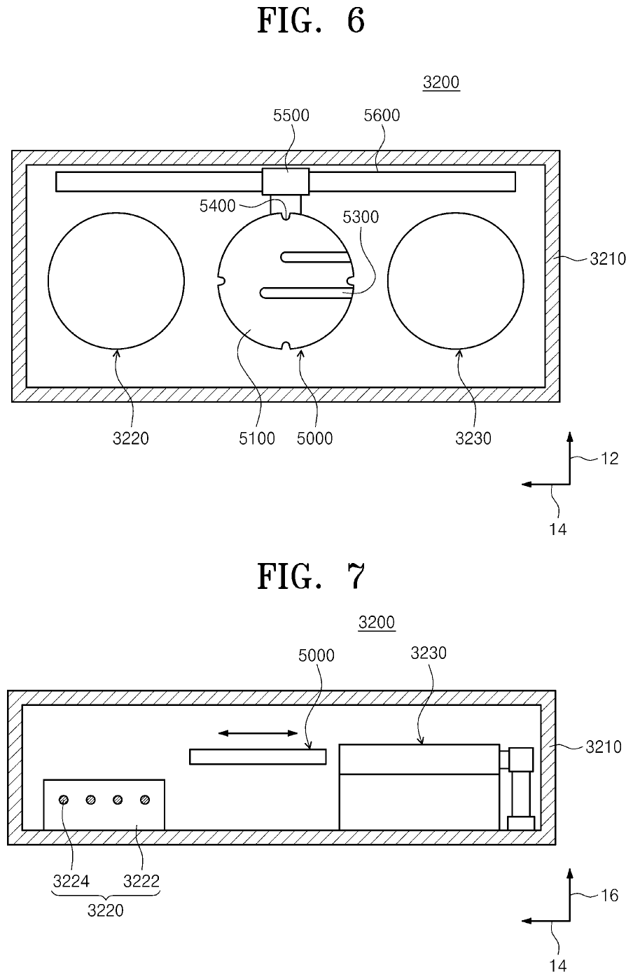

FIG. 6 is a plan view schematically illustrating an example of a heat treatment chamber of FIG. 4. FIG. 7 is a front view of the heat treatment chamber of FIG. 6.

Referring to FIGS. 6 and 7, the heat treatment chamber 3200 may include a housing 3210, a cooling unit 3220, a heating unit 3230, and a transfer unit 5000 having a transfer plate 5100.

The housing 3210 has a substantially rectangular parallelepiped shape. A transfer entrance (not illustrated), through which the substrate “W” is introduced and exits, is formed in a side wall of the housing 3210. The transfer entrance may maintain an opened state. Optionally, a door (not illustrated) may be provided to open and close the transfer entrance. The cooling unit 3220, the heating unit 3230, and the transfer unit 5000 are provided in the housing 3210. The cooling unit 3220 and the heating unit 3230 are provided side by side along the second direction 14. According to an embodiment, the cooling unit 3220 may be located closer to the transfer chamber 3400 than the heating unit 3230.

The cooling unit 3220 have a cooling plate 3222. The cooling plate 3222 may have a substantially circular shape when viewed from a top. The cooling plate 3222 is provided with a cooling member 3224. According to an embodiment, the cooling member 3224 may be formed in an interior of the cooling plate 3222 and may be provided with a passage, through which a cooling fluid flows.

The heating unit 3230 is provided as a device that heats a substrate at a temperature that is higher than a room temperature. The heating unit 3230 heats the substrate “W” at a normal pressure or a pressure that is lower than the normal pressure. The heating unit 3230 may perform a baking process on the substrate “W”. The heating unit 3230 may be provided with a substrate treating apparatus 3300 that performs a baking process on the substrate “W”.

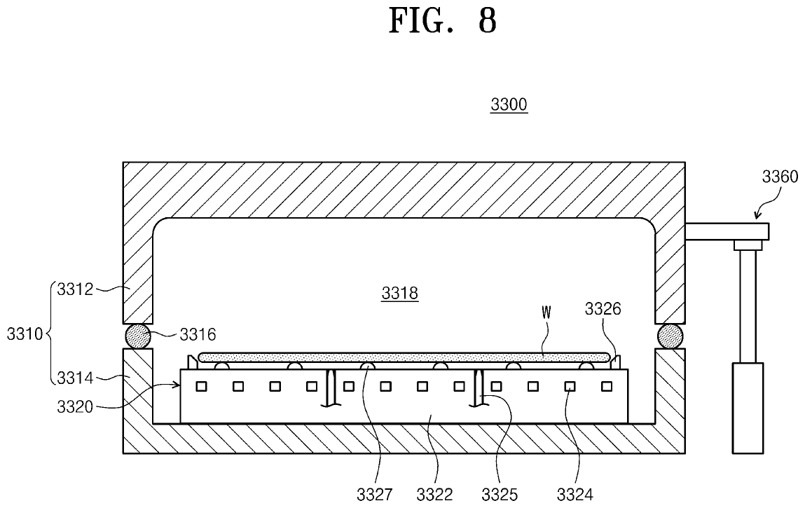

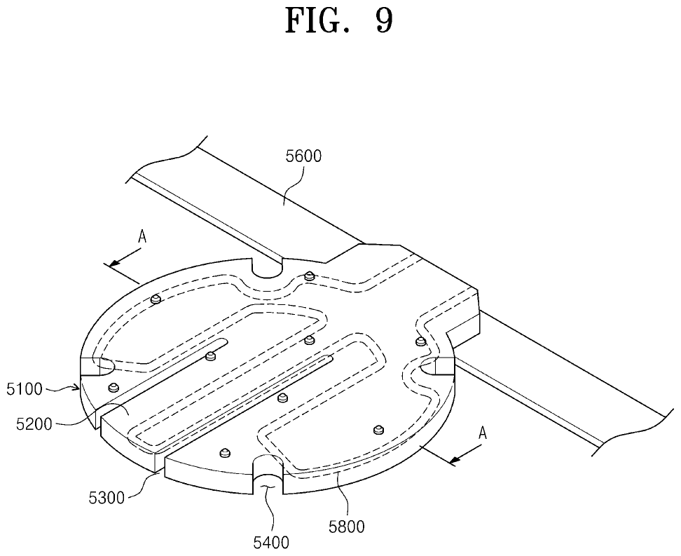

FIG. 8 is a view illustrating the substrate treating apparatus provided in a heating unit of FIG. 7.

Referring to FIG. 8, the heating unit 3230 includes a chamber 3310, a support unit 3320, and an elevation unit 3360.

The chamber 3310 includes an upper chamber 3312, a lower chamber 3314, and a sealing member 3316. The upper chamber 3312 may have a vessel shape, a lower side of which is opened. The lower chamber 3314 may have a vessel shape, an upper side of which is opened. The lower chamber 3314 may be disposed on a lower side of the upper chamber 3312. The upper chamber 3312 and the lower chamber 3314 may be combined to define an interior space 3318.

Furthermore, the sealing member 3316 may be provided between the upper chamber 3312 and the lower chamber 3314. The sealing member 3316 is located between the upper chamber 3312 and the lower chamber 3314. The sealing member 3316 seals the interior space from an outside when the upper chamber 3312 and the lower chamber 3314 contact each other. The sealing member 3316 may have an annular ring shape. The sealing member 3316 may be fixedly coupled to an upper end of the lower chamber 3314.

The support unit 3320 supports the substrate “W” in the interior space 3318. Furthermore, the support unit 3320 may heat the substrate “W”. The support unit 3320 is fixedly coupled to the lower chamber 3314. The support unit 3320 may include a support plate 3322, a heater 3324, a lift pin 3325, a guide 3326, and a support pin 3327.

The support plate 3322 has a circular disk shape. An upper surface of the support plate 3322 may have a diameter that is larger than that of the substrate “W”. The upper surface of the support plate 3322 may function as a seating surface, on which the substrate “W” is positioned. Furthermore, the support plate 3322 may be provided with the heater 3324. The heater 3324 may heat the substrate “W”. Furthermore, a plurality of heaters 3324 may be provided. The plurality of heaters 3324 may heat the substrate “W” to different temperatures according to areas. For example, some of the plurality of heaters 3324 may heat a central area of the substrate “W” to a first temperature, and others of the plurality of heaters 3324 may heat middle and edge areas of the substrate “W” to a second temperature. The first temperature and the second temperature may be different.

The lift pin 3325 may move the substrate “W” upwards and downwards. A plurality of lift pins 3325 may be provided. The lift pins 3325 may move the substrate “W” upwards and downwards when the substrate “W” is carried into or out of the interior space 3318.

The guide 3326 guides the substrate “W” such that the substrate “W” is positioned at a proper location of the seating surface. The guide 3326 has an annular ring shape that surrounds the seating surface. The guide 3326 has a diameter that is larger than that of the substrate “W”. An inner surface of the guide 3326 has a downwardly inclined shape as it becomes closer to a central axis of the support plate 3322. Accordingly, the substrate “W” that is hung on the inner surface of the guide 3326 is moved to a proper location along the inclined surface. Furthermore, the guide 3326 may prevent air flows introduced between the substrate “W” and the seating surface by a low degree.

The support pin 3327 may be provided at an upper portion of the support plate 3322. A plurality of support pins 3327 may be provided. A plurality of support pins 3327 may be spaced apart from each other. The support pins 3327 may support a lower surface of the substrate “W”. The support pins 3327 may prevent the substrate “W” from directly contacting the support plate 3322.

An exhaustion unit (not illustrated in the drawings) may exhaust the interior space 3318. The exhaustion unit may form air flows in the interior space 3318. The exhaustion unit may form upstream flows in the interior space 3318. The exhaustion unit may be provided in the upper chamber 3312.

A gas supply unit (not illustrated in the drawings) may supply gas to the interior space 3318. The gas supply unit may eject the gas to the substrate “W” supported by the support unit 3320. The gas supplied by the gas supply unit may be exterior air. The gas supplied by the gas supply unit may be fresh air. The gas supplied by the gas supply unit may be gas, a temperature and a humidity of which are adjusted. The gas supply unit may form downstream flows in the interior space 3318. The gas supply unit may be provided in the upper chamber 3312.

The elevation unit 3360 may move any one of the upper chamber 3312 and the lower chamber 3314. For example, the elevation unit 3360 may move the upper chamber 3312 upwards and downwards. The elevation unit 3360 may move the upper chamber 3312 to an opened location or a blocked location. Here, the opened location is a location at which the upper chamber 3312 and the lower chamber 3314 are spaced apart from each other so that the interior space 3318 is opened. The blocked location is a location at which the interior space 3318 is closed from the outside by the upper chamber 3312 and the lower chamber 3314.

The controller (not illustrated in the drawings) may control a substrate treating apparatus 3300. The controller may control a gas supply unit(not illustrated in the drawings). The controller may control an exhaustion unit (not illustrated in the drawings).

Hereinafter, the transfer plate according to the inventive concept will be described in more detail with reference to the drawings.

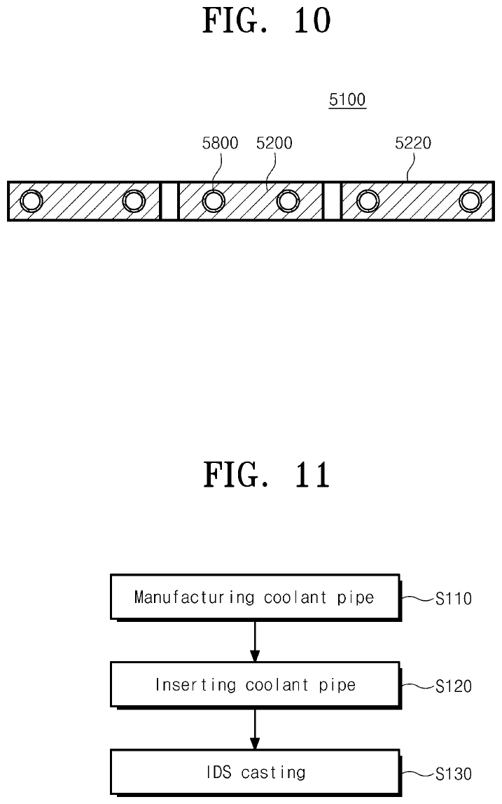

FIG. 9 is a view illustrating a transfer plate according to the inventive concept. FIG. 10 is a cross-sectional view taken along line A-A of FIG. 9.

Referring to FIGS. 9 and 10, the transfer plate 5100 may include a base plate 5200 and a coolant pipe 5800. The transfer plate 5100 is provided as an integral cast, in which the coolant pipe 5800 that provides a cooling passage is inserted into the base plate 5200 through casting (or cold welding).

The transfer plate 5100 according to the inventive concept may be a cooling plate that transfers the substrate “W” between the cooling unit 3220 and the heating unit 3230 in the heat treatment chamber 3200. Then, the transfer plate 5100 may cool the substrate in a process of transferring the substrate “W”. Alternatively, the base plate 5200 may be positioned on an upper surface of the cooling plate 3222 of the cooling unit 3220 while the substrate “W” is positioned on the base plate 5200.

The base plate 5200 has a substantially disk shape, and has a diameter corresponding to the substrate “W”. The base plate 5200 may be formed of a conductive material. The base plate 5200 may be formed of aluminum or an aluminum alloy. The base plate 5200 may be coated with an insulation layer 5220. Then, the insulation layer 5220 may include hard anodizing.

A notch 5400 is formed at an edge of the base plate 5200. The notch 5400 may have a shape corresponding to the boss 3429 formed in the hand 3420 of the above-described transfer robot 3422 and 3424. Further, the number of the notches 5400 is the number corresponding to the bosses 3429 formed in the hand 3420, and the notches 5400 are formed at locations corresponding to the bosses 3429. When the upward/downward locations of the hand 3420 and the base plate 5200 are changed in a state, in which the hand 3420 and the base plate 5200 are arranged in upward/downward directions, the substrate “W” is transferred between the hand 3420 and the base plate 5200. The base plate 5200 may be mounted on a guide rail 5600, and may be moved between a first area 3212 and a second area 3214 along the guide rail 5600 by a driver 5500.

A plurality of slit-shaped guide grooves 5300 are provided in the base plate 5200. The guide grooves 5300 extend from an end of the base plate 5200 to an interior of the base plate 5200. Lengthwise directions of the guide grooves 5300 are provided along the second direction 14, and the guide grooves 5300 are located to be spaced apart from each other along the first direction 12. The guide grooves 5300 prevent the base plate 5200 and the lift pin 3325 from interfering with each other when the substrate “W” is delivered between the base plate 5200 and the heating unit 3230.

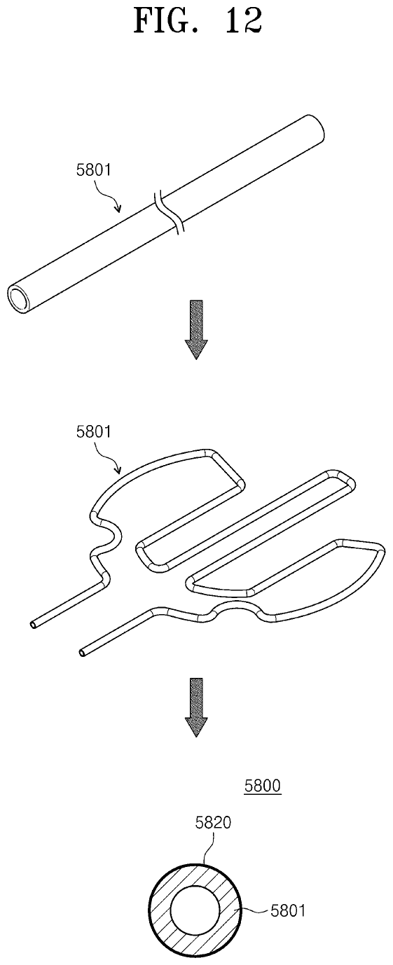

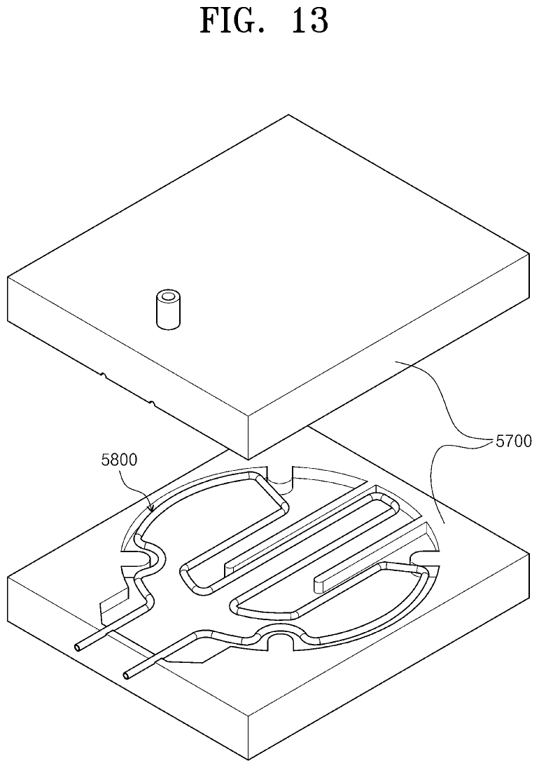

The coolant pipe 5800 may be formed of a material that is different from that of the material of base plate 5200 of a casting material. For example, the material of the coolant pipe 5800 may be a stainless steel material, and the casting material may be aluminum or an aluminum alloy. The coolant pipe 5800 has a plating film 5820 (see FIG. 12) to form an intermetallic compound between interfaces in a casting process. The plating film 5820 may be any one of Zn, Ni, and Ni—P.

The coolant pipe 5800 provides a passage, through which the coolant flows. The base plate 5200 is cooled by the coolant that flows through the coolant pipe 5800. Meanwhile, the coolant may include various fluids, such as cooling water or known coolants, and air, as long as it is for the purpose of cooling, and for example, cooling water that may be easily treated, has an excellent cooling efficiency, and has an excellent fluidity may be used as the coolant.

In this way, the transfer plate 5100 of the inventive concept has a high anti-oxidation/anti-corrosion property due to application of the coolant pipe 5800 of a stainless steel material, and has an excellent thermal conductivity due to bonding of interfaces of the coolant pipe 5800 and a member (the base plate 5200).

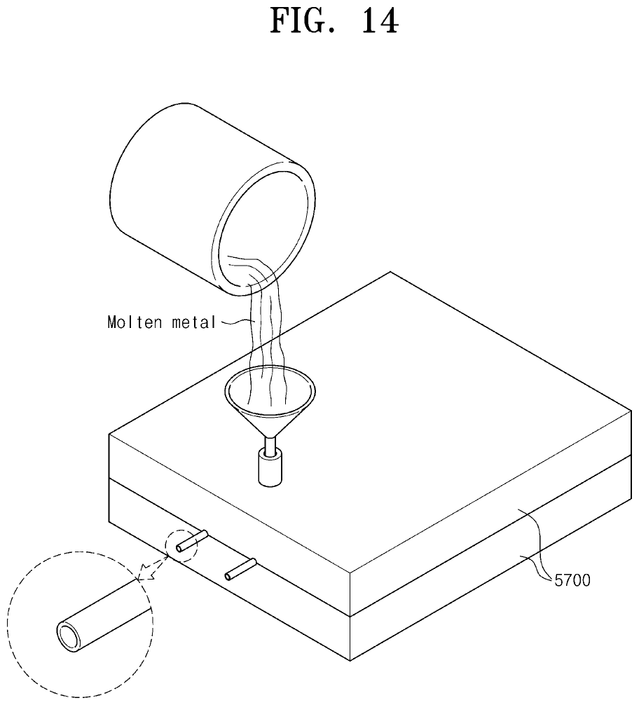

FIG. 11 is a flowchart illustrating a method for manufacturing a transfer plate. FIGS. 12 to 15 are views illustrating a process of manufacturing the transfer plate.

Referring to FIGS. 11 to 15, the process of manufacturing the transfer plate may include an operation of manufacturing a coolant pipe by using a tubular pipe, an operation of inserting the coolant pipe into a casting mold that defines a plate, and an operation of casting the transfer plate by injecting a molten metal into the casting mold.

As illustrated in FIG. 12, a tubular pipe 5801 that is to be a flow passage is prepared. The tubular pipe 5801 is bent in correspondence to an actual shape of the passage that is to be formed in the cast product (the transfer plate). The tubular pipe may be bent in various forms. An outer peripheral surface of the bent tubular pipe 5801 is surface-treated. The surface treatment is provided to form an intermetallic compound between interfaces in the casting process. The surface treatment may be any one of Zn plating, Ni plating, and Ni—P plating.

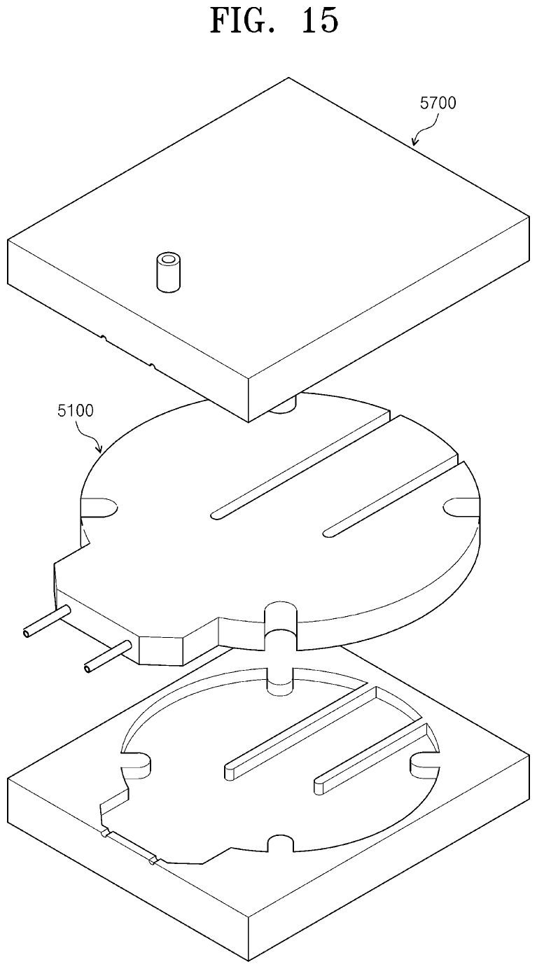

As in FIG. 13, the prepared coolant pipe 5800 is inserted into and fixed to a casting mold 5700 manufactured in correspondence to the shape of the transfer plate. When the molten metal is cooled and machined after being injected into an entrance of the casting mold 5700, the transfer plate 5100 as illustrated in FIG. 15 is manufactured. Although not illustrated, the method may further include an operation of surface-treating the transfer plate 5100 through anodizing after the operation of casting the transfer plate.

A melting temperature of the coolant pipe 5800 has to be higher than a melting temperature of a metal that is to be cast. In the operation of casting the transfer plate 5100, insert die casting may be used.

As described above, the inventive concept provides a manufacturing method that may implement a shape of the transfer plate of a cooling function, which is to be manufactured, by inserting the coolant pipe 5800 into a mold manufactured in a shape of the base plate 5100 and casting the coolant pipe 5800, and may show an economic performance while securing a safety of a coolant passage by integrally forming the transfer plate having the coolant pipe 5800 through casting.

Referring to FIGS. 3 and 4 again, a plurality of liquid treatment chambers 3600 are provided. Some of the liquid treatment chambers 3600 may be provided to stack on each other. The liquid treatment chambers 3600 are disposed on one side of the transfer chamber 3400. The liquid treatment chambers 3600 are arranged side by side along the first direction 12. Some of the liquid treatment chambers 3600 are provided at locations that are adjacent to the index module 20. Hereinafter, the liquid treatment chambers are referred to as front liquid treatment chambers 3602. Others of the liquid treatment chambers 3600 are provided at locations that are adjacent to the interface module 40. Hereinafter, the liquid treatment chambers are referred to as rear liquid treatment chambers 3604.

The front liquid treatment chambers 3602 apply a first liquid to the substrate “W”, and the rear liquid treatment chambers 3604 apply a second liquid to the substrate “W”. The first liquid and the second liquid may be different kinds of liquids. According to an embodiment, the first liquid is a reflection preventing film, and the second liquid is a photoresist. The photoresist may be applied onto the substrate “W”, on which the reflection preventing film is applied. Optionally, the first liquid may be the photoresist, and the second liquid may be the reflection preventing film. In this case, the reflection preventing film may be applied onto the substrate “W”, on which the photoresist is applied. Optionally, the first liquid and the second liquid may be a liquid of the same kind, and both may be the photoresist.

A plurality of buffer chambers 3800 are provided. Some of the buffer chambers 3800 are disposed between the index module 20 and the transfer chamber 3400. Hereinafter, such buffer chambers will be referred to as front buffers 3802. A plurality of front buffers 3802 are provided, and are stacked on each other along an upward/downward direction. Other of the buffer chambers 3802 and 3804 are disposed between the transfer chamber 3400 and the interface module 40. Hereinafter, such buffer chambers will be referred to as rear buffers 3804. A plurality of rear buffers 3804 are provided, and are stacked on each other along an upward/downward direction. The front buffers 3802 and the rear buffers 3804 temporarily preserve a plurality of substrate “W”. The substrates “W” preserved in the front buffers 3802 are carried in or out by the index robot 2200 and the transfer robot 3422. The substrates “W” preserved in the rear buffers 3804 are carried in or out by the transfer robot 3422 and a first robot 4602.

The development block 30b has the heat treatment chamber 3200, the transfer chamber 3400, and the liquid treatment chamber 3600. The heat treatment chamber 3200, the transfer chamber 3400, and the liquid treatment chamber 3600 of the development block 30b have structures and arrangements that are substantially similar to those of the heat treatment chamber 3200, the transfer chamber 3400, and the liquid treatment chamber 3600 of the application block 30a, and thus a description thereof will be omitted. However, in the development block 30b, all of the liquid treatment chambers 3600 supply a development liquid in the same way and provide the development liquid into the development chamber that develop the substrate.

The interface module 40 connects the treatment module 30 to an external exposure apparatus 50. The interface module 40 has an interface frame 4100, an additional process chamber 4200, an interface buffer 4400, and a transfer member 4600.

A fan filter unit that forms downward flows in an interior thereof may be provided at an upper end of the interface frame 4100. The additional process chamber 4200, the interface buffer 4400, and the transfer member 4600 are disposed in an interior of the interface frame 4100. The additional process chamber 4200 may perform a specific additional process before the substrate “W”, on which a process has been performed in the application block 30a, is carried into the exposure apparatus 50. Optionally, the additional process chamber 4200 may perform a specific additional process before the substrate “W”, on which a process has been performed in the exposure apparatus 50—, is carried into the development block 30b. According to an example, the additional process may be an edge exposing process of exposing an edge area of the substrate “W”, an upper surface cleaning process of cleaning an upper surface of the substrate “W”, or a lower surface cleaning process of cleaning a lower surface of the substrate “W”. A plurality of additional process chambers 4200 may be provided, and may be stacked on each other. All of the additional process chambers 4200 may perform the same process. Optionally, some of the additional process chambers 4200 may perform different processes.

The interface buffer 4400 provides a space, in which the substrate “W” that is transferred between the application block 30a, the process chambers 4200, the exposure apparatus 50, and the development block 30b temporarily stays while being transferred. A plurality of interface buffers 4400 may be provided, and the plurality of interface buffers 4400 may be stacked on each other.

According to an embodiment, the additional process chambers 4200 may be disposed on one side of the transfer chamber 3400 with respect an extension line in a lengthwise direction of the transfer chamber 3400, and the interface buffers 4400 may be disposed on another side of the transfer chamber 3400.

The transfer member 4600 transfers the substrate “W” between the application block 30a, the additional process chambers 4200, the exposure apparatus 50, and the development block 30b. The transfer member 4600 may be one or a plurality of robots. According to an example, the transfer member 4600 has the first robot 4602 and a second robot 4606. The first robot 4602 may transfer the substrate “W” between the application block 30a, the additional process chamber 4200, and the interface buffer 4400, the second robot 4606 may transfer the substrate “W” between the interface buffer 4400 and the exposure apparatus 50, and the second robot 4606 may transfer the substrate “W” between the interface buffer 4400 and the development block 30b.

The first robot 4602 and the second robot 4606 include hands, on which the substrates “W” are positioned, respectively, and the hands may be moved forwards and rearwards, may be rotated about an axis that is parallel to the third direction 16, and may be moved along the third direction 16.

The hands of the index robot 2200, the first robot 4602, and the second robot 4606 may have the shapes as the hands 3402 of the transfer robots 3422 and 3424. Optionally, the hands of the robots that directly deliver and receive the substrate “W” to and from the transfer plate 3240 of the heat treatment chamber, and the hands of the others may have a different shape.

According to an embodiment, the index robot 2200 may directly deliver and receive the substrate “W” to and from the heating unit 3230 of the front heat treatment chamber 3200 provided to the application block 30a.

Furthermore, the transfer robot 3422 provided to the application block 30a and the development block 30b may directly deliver and receive the substrate “W” to and from the transfer plate 3240 located in the heat treatment chamber 3200.

According to an embodiment of the inventive concept, an anti-oxidation performance and an anti-corrosion performance are excellent as a coolant pipe of a stainless steel material is used.

According to an embodiment of the inventive concept, a thermal conductivity is excellent due to bonding of interfaces of the coolant and the members, whereby a cooling performance may be improved.

According to an embodiment of the inventive concept, products of various shapes may be manufactured according to casting.

According to an embodiment of the inventive concept, a neck section may be eliminated by using an inner diameter of the coolant pipe.

According to the embodiment of the inventive concept, a surface treatment through anodizing may be possible.

The effects of the inventive concept are not limited to the above-mentioned effects, and the unmentioned effects can be clearly understood by those skilled in the art to which the inventive concept pertains from the specification and the accompanying drawings.

The above detailed description exemplifies the inventive concept.

Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

1.-8. (canceled)

9. A cooling plate for cooling a substrate, which is integrally cast by inserting a coolant pipe bent in a shape of a cooling passage, and wherein a material of the coolant pipe is different from a casting material.

10. The cooling plate of claim 9, wherein the material of the coolant pipe is a stainless steel material, and
wherein the casting material is aluminum or an aluminum alloy.

11. The cooling plate of claim 10, wherein the coolant pipe has a plate film on an outer peripheral surface thereof.

12. The cooling plate of claim 11, wherein the plating film is formed of any one of Zn, Ni, and Ni—P.

13. The cooling plate of claim 10, wherein the cooling plate for cooling the substrate includes a guide hole that extends from an outer surface thereof to an inner side.

14. A substrate treating apparatus comprising:
a housing;
a heating unit located in the housing and having a heating plate configured to heat a substrate;
a transfer unit located in the housing and having a transfer plate configured to transfer the substrate; and
a cooling unit configured to cool the heating plate or the heated substrate,
wherein the substrate treating apparatus includes a transfer plate,
wherein the cooling unit includes a cooling passage provided in an interior of the transfer plate, and
wherein the transfer plate is an integral cast, into which a coolant pipe that provides the cooling passage through casting.

15. The substrate treating apparatus of claim 14, wherein an outer peripheral surface of the coolant pipe is surface-treated.

16. The substrate treating apparatus of claim 15, wherein the surface-treating of the outer peripheral surface of the coolant pipe is any one of Zn plating, Ni plating, and Ni—P plating.

17. The substrate treating apparatus of claim 14, wherein materials of the coolant pipe and the cast are different materials.

18. The substrate treating apparatus of claim 17, wherein the coolant pipe is formed of a stainless steel material, and
wherein the material of the cast is an aluminum or aluminum alloy material.

19. The substrate treating apparatus of claim 14, wherein the heating unit further includes:
lift pins configured to move in a pin hole formed in the heating plate upwards and downwards and feed the substrate to the transfer unit,
wherein the transfer unit further includes:
a driving member configured to move the transfer plate between a first location that is adjacent to a first side wall having a substrate entrance of the housing and a second location corresponding to an upper side of the heating plate, and
wherein the transfer plate includes:
a guide hole, into which the lift pins are inserted such that an interference or a collision with the lift pins is prevented when the transfer plate move from the first location to the second location.

20. The substrate treating apparatus of claim 19, wherein the guide hole extends from an outer surface of the transfer plate to an inner side.
